(19) United States
(12) Patent Application Publication
(10) Pub. No.: US 2009/0225341 A1
(43) Pub. Date: Sep. 10, 2009

(54) Test Chart and Color Calibration Method

(75) Inventor: Yoshihiko MATSUZAWA, Matsumoto-shi (JP)

Correspondence Address: HOGAN & HARTSON L.L.P., 1999 AVENUE OF THE STARS, SUITE 1400, LOS ANGELES, CA, 90067, US

(73) Assignee: SEIKO EPSON CORPORATION, Tokyo (JP)

(21) Appl. No.: 12/397,162

(22) Filed: Mar. 3, 2009

(30) Foreign Application Priority Data
Mar. 4, 2008 (JP) 2008-053813

(51) Int. Cl. H04N 1/60; G03F 3/08

(52) U.S. Cl. 358/1.9; 358/518

(57) ABSTRACT

There is provided a test chart used for a color calibration for correcting gradation. The test chart includes a plurality of rectangular patches respectively corresponding to each gradation for each color, and the plurality of patches having different colors are aligned in the order so that the colors whose hues are close become adjacent to each other in a short side direction of the patches.

### BACKGROUND

1. Technical Field

The present invention relates to a test chart and a color calibration method.

2. Related Art

A color printer capable of displaying a plurality of colors has been used. In such a color printer, a color calibration for improving color reproducibility is performed. When the color calibration is performed, a test chart for the color calibration is printed. Then, a calorimetric value in a color space is obtained by performing colorimetry on the chart, and any of colors outputted by the printer is to be corrected based on the calorimetric result.

A correction can be performed with a high accuracy by performing the correction based on many calorimetric results. Accordingly, it is desirable that patches having many gradations are recorded on a paper as much as possible (See JP-A-2000-283852, JP-A-2001-99711, JP-A-2005-47187).

A calorimeter performs colorimetry while moving a head in order to improve colorimetry speed. A small gap is provided between the head and the test chart in order to perform colorimetry while moving the head. There is a case that a part of emitted colorimetry light is leaked to an area outside a colorimetric target when the gap is provided. When a part of colorimetry light is leaked to an area outside the calorimetric target in the case where a patch that is the calorimetric target is small, there is a case that the leaked light is reflected by an adjacent patch to apply an effect to the colorimetric value of the patch of the calorimetric target. When the patch of the calorimetric target is fully large, all of the light is reflected by the patch of the calorimetric target, so that the colorimetry is insusceptible to the leaked light. However, if the size of the patch is increased, the number of the patches that can be recorded on one paper is reduced. Accordingly, it is desired to provide a test chart in which patches are aligned so that the colorimetry is insusceptible to the leaked light from the adjacent patch without increasing the size of the patch.

### SUMMARY

An advantage of some aspects of the invention is to provided a test chart and a color calibration method by which colorimetry is insusceptible to another patch.

According to an aspect of the invention, there is provided a test chart used for a color calibration for correcting gradation. The test chart includes a plurality of rectangular patches respectively corresponding to each gradation for each color, and the plurality of patches having different colors are aligned in the order so that the colors whose hues are close become adjacent to each other in a short side direction of the patches.

Herewith, colorimetry can be insusceptible to another patch.

It is desirable that the plurality of patches having different colors are aligned in the order of the patch having higher gradation in the short side direction of the patches in the test chart. Further, it is desirable that the plurality of patches having different colors are aligned so that a gradation difference of the patches adjacent to each other becomes small in the short side direction of the patches. Further, it is desirable that the plurality of patches having different colors are aligned so that a distance of colors of the patches adjacent to each other in a color space becomes close. Further, it is desirable that the color space is CIE L*a*b* color space.

Further, it is desirable that the plurality of patches having different colors are also aligned so that a hue difference of the patches adjacent to each other becomes small in the long side direction of the patches.

Herewith, colorimetry can be insusceptible to another patch.

According to another aspect of the invention, there is provided a calibration method including performing colorimetry on a test chart that includes a plurality of rectangular patches respectively corresponding to each gradation for each color, the plurality of patches having different colors being aligned in the order so that the colors whose hues are close become adjacent to each other in a short side direction of the patches, and performing a color calibration based on a calorimetric result of the test chart.

Herewith, colorimetry can be insusceptible to another patch.

Other characteristics of the invention will be clear from the description of this specification and accompanying drawings.

### BRIEF DESCRIPTION OF THE DRAWINGS

The invention will be described with reference to the accompanying drawings, wherein like numbers reference like elements.

FIG. 1 is a diagram showing a structure of a color calibration system of a printer.

FIGS. 2A, 2B are diagrams illustrating a structure of a colorimeter.

FIG. 3 is a diagram illustrating an appearance in which light emitted form a head of the calorimeter is leaked.

FIG. 4 is a diagram showing a chart for measuring an effect of a white patch to a black patch.

FIG. 5 is a diagram showing a result of an effect of the white patch to the black patch.

FIG. 6A is a diagram illustrating an arrangement of black patches when gradation is smoothly changed, and FIG. 6B is a diagram illustrating L*values of the black patches when gradation is smoothly changed.

FIG. 7 is a diagram illustrating a color dispersion level occurred on a surface of a paper when printing is performed on the paper.

FIG. 8 is a diagram illustrating a test chart according to an embodiment.

FIG. 9 is a diagram illustrating a hue angle in L*a*b* color space.

### DESCRIPTION OF EXEMPLARY EMBODIMENTS

### Embodiment

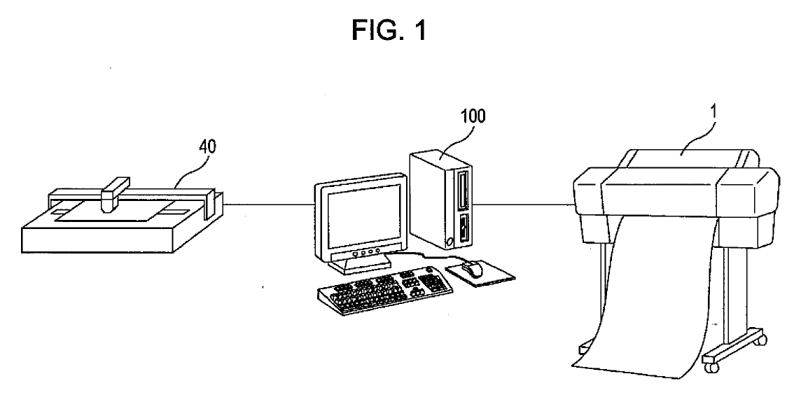

FIG. 1 is a diagram showing a structure of a color calibration system of a printer. A computer 100, a printer 1, and a calorimeter 40 are shown in FIG. 1.

### Colorimeter 40

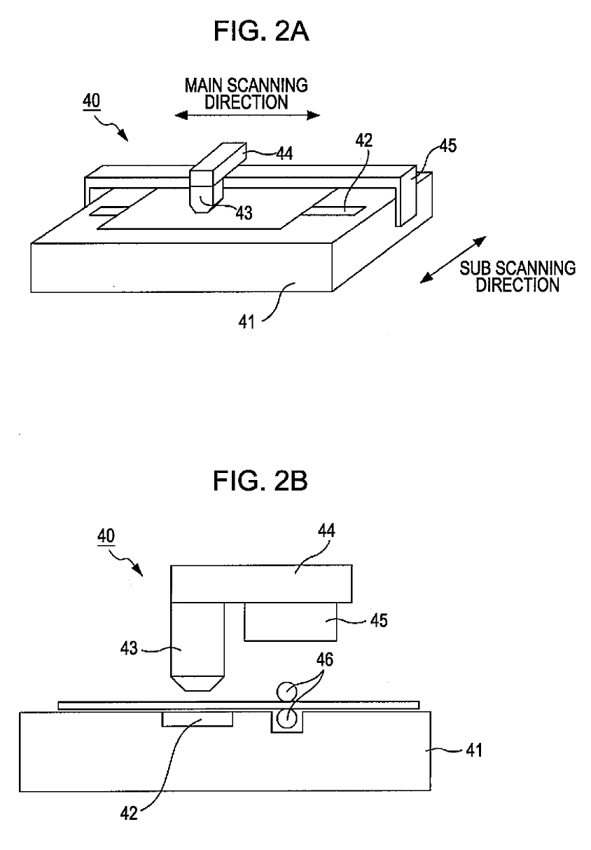

FIGS. 2A, 2B are diagrams illustrating a structure of the calorimeter 40. An appearance of the calorimeter 40 is shown in FIG. 1. The calorimeter 40 is equipped with a calorimetry stand 41, a backing 42, a colorimetry head 43, a calorimeter carriage 44, a rail 45, and paper feed rollers 46.

The backing 42 formed by a white plate is fixed on the calorimetry table 41. The colorimetry head 43 scans a paper on the backing 42 and performs colorimetry. The calorimeter carriage 44 is equipped with a motor not shown, and is moved on the rail 45 and moves the calorimetry head 43 in a main scanning direction. The paper feed rollers 46 transport a paper in a sub scanning direction by a predetermined amount for each time colorimetry in the main scanning direction is completed. The calorimeter 40 detects a color component amount of a plurality of color components L*, a*, b* based on L*a*b* color space of CIE(1076) standard by orienting the calorimetry head 43 toward a target of colorimetry, and creates calorimetric values L*, a*, b* corresponding the detected amounts. That is, when calorimetry is performed to each point, a pair of calorimetric values constituted by L* value, a* value, and b* value can be obtained. Herein, CIE L*a*b* color space is an even color space in which a plurality of color components L*, a*, b* are color component amounts, and the even color space does not depend on a device. Note that L* shows lightness and a*, b* show color coordinates showing hue and saturation.

The colorimeter 40 outputs calorimetric values created by performing colorimetry to the computer 100. Note that the color space of the calorimetric values to be output may be CIE L*u*v* color space.

### Printer 1

The printer 1 is a printer for ejecting an ink drop on a paper to form an image. The printer 1 includes a head in which inks of a plurality of colors are mounted. The printer 1 ejects ink while moving the head in a direction perpendicular to a transport direction while intermittently transporting a paper in the transport direction of the paper. An image is formed by correction of fine ink adhered on the paper. The printer 1 used here is capable of ejecting nine type of inks, cyan C, light cyan LC, green Gr, yellow Y, orange Or, light magenta LM, magenta M, light back LK, and black K.

Herein, the aforementioned nine colors of inks are used. However, types of color are not limited to this. Further, the ink to be used may be a pigment ink in which a color material made of a pigment is mixed, or may be a dye ink in which a color material made of a dye is mixed. Herein, an ink ejection type printer is exemplified. However, a color laser printer that forms an image on a paper by using a plurality of color toners may be used.

### Computer 100

The computer 100 includes a processing device and a storage device not shown. The processing device is a calculation device, for example, such as a CPU. Further, the storage device is formed by, for example, a ROM, a RAM, a hard disc drive, a CD-ROM drive, or the like, and various programs are stored therein. The RAM and the hard disc drive are also used as an area for storing a calculation result as needed when performing the programs. The computer 100 is connected with the printer 1 and the colorimeter 40 via an interface. The computer 100 makes the printer 1 to print a desired image by transmitting print data to the printer 1. Further, the computer 100 outputs a command of colorimetry to the calorimeter 40 and obtains a calorimetric result.

### Color Calibration

The printer has a color output characteristic that is slightly different for each printer. In order to correct the difference and improve color reproducibility, a color calibration is performed. The color calibration is performed by, for example, the following steps. First, the printer prints a test chart. Then, the printed test chart is fixed to the calorimeter, and colorimetry of the test chart is performed. Then, a deviation amount of the printed color is obtained based on the measured calorimetric value. Then, a conversion table for correcting the deviation amount is created. Then, a printing is performed while correcting the deviation amount by using the conversion tale. Herewith, printing can be performed with adequate colors.

### Effect of Adjacent Patch When Performing Colorimetry

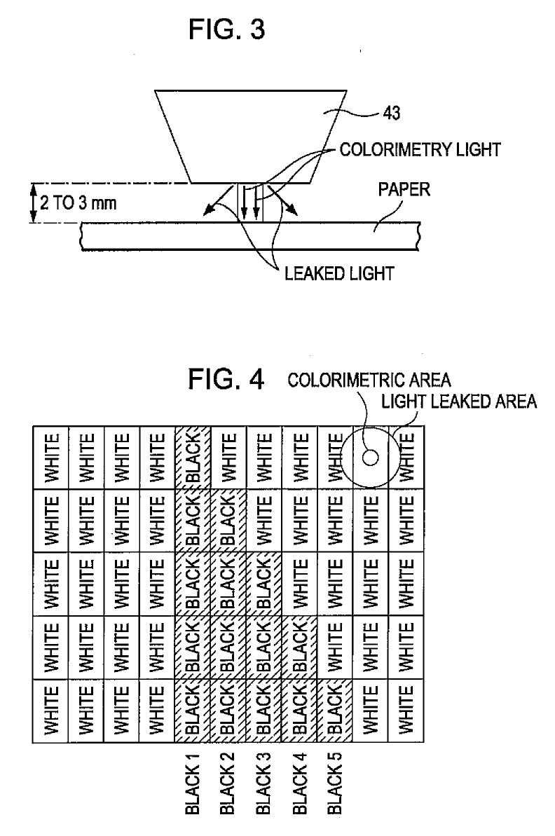

FIG. 3 is a diagram illustrating an appearance when light emitted from the head 43 of the calorimeter 40 is leaked. In FIG. 3, an appearance is shown in which light for colorimetry (colorimetry light) from the head 43 of the calorimeter 40 is emitted on the paper in which patches are printed. The colorimetry light is reflected by the patch, and the light having a color corresponding to the patch is returned to the head 43. A colorimetry unit mounted in the head 43 measures the reflected light, and outputs L* value, a* value, b* value as calorimetric values.

A gap of about 2 to 3 mm is provided between the head 43 of the calorimeter 40 and the paper in which the patches are printed. The gap is provided in order to improve colorimetry speed by performing colorimetry on the plurality of patches while moving the head 43 in the main scanning direction. In this manner, since a gap is provided between the head 43 and the paper, there is a case that colorimetry light is leaked in a direction deviated from the patch of a colorimetric target. Consequently, there is a case that the calorimetric value of the patch of the calorimetric target is negatively affected by reading the light reflected from a patch that is different from the patch of the calorimetric target by the head 43.

FIG. 4 is a diagram showing a chart for measuring an effect of a white patch to a black patch. One black patch (black 1) is arranged in the first line, and a plurality of white patches are arranged at each of the left and right sides thereof. Two black patches (black 1, black 2) are arranged in the second line and a plurality of white patches are arranged at each of the left and right sides thereof. Three black patches (black 1, black 2, black 3) are arranged in the third line, and a plurality of white patches are arranged at each of the left and right sides thereof. For black patches (black 1, black 2, black 3, black 4) are arranged in the forth line, and a plurality of white patches are arranged at each of the left and right sides thereof. Five black patches (black 1, black 2, black 3, black 4, black 5) are arranged in the fifth line, and a plurality of white patches are arranged at each of the left and right sides thereof.

Further, a calorimetric area of colorimetry light and a light leaked area are shown in FIG. 4. The calorimetric area is an area in which colorimetry light for performing colorimetry on a target is emitted. Further, the light leaked area is an area in which the colorimetry light is leaked to the periphery of the calorimetric target. Note that the size of the patch used here is 7 mm in the short side direction and 14 mm in the long side direction. The calorimetric area is the area that is included in one patch. However, the light leaked area includes a part of the adjacent patch in the short side direction. That is, the diameter of the colorimetric area is not more than 7 mm and the diameter of the light leaked area is not less than 7 mm.

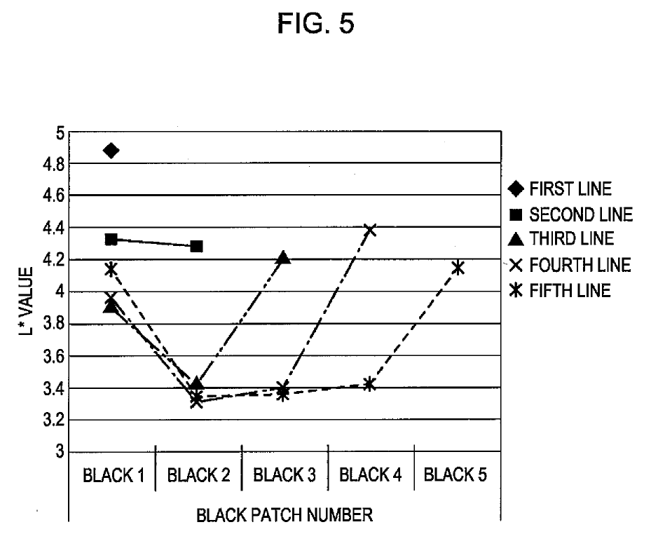

FIG. 5 is a diagram showing a result of an effect of the white patch to the black patch. When colorimetry is performed on the black patch, there is a case that the colorimetry is affected by the adjacent white patch. Herein, the L* value of the patch “black 1” is 4.9. When colorimetry is performed on the black patches of the second line, the L* values of “black 1” and “black 2” are respectively about 4.3. When colorimetry is performed on the black patches of the third line, the L* values of “black 1” to “black 3” are respectively 3.9, 3.4, 4.2. When colorimetry is performed on the black patches of the fourth line, the L* values of “black 1” to “black 4” are respectively 4.0, 3.4, 3.4, 4.4. When colorimetry is performed on the black patches of the fifth line, the L* values of “black 1” to “black 5” are respectively 3.9, 3.4, 3.4, 3.4, 4.2.

Note that the reason for describing about only L* value in L*a*b* color space is that a* value and b* value are close to approximately zero, so that the calorimetric value of black color can be approximately expressed by L* value showing lightness. Accordingly, only L* value is used here to describe a calorimetric result of the black patch.

With reference to the aforementioned result, when the white patches are adjacent, the light leaked to the white patch is reflected and introduced in the head 43. Herewith, the L* value becomes a value that is different from the original calorimetric value of the colorimetric target. However, when the black patches having the same color are adjacent to the both sides, it is considered that the back patch that is sandwiched by the black patches is hardly affected by the white patch. It is considered that the black patch sandwiched by the black patches can be viewed as a continuous one black patch to lessen the effect of the leaked light. Note that it is considered that the original L* value of the black patch is 3.4.

In this manner, when the size of the patch of the calorimetric target is sufficiently large, the colorimetry is not affected by the leaked light. However, if the size of the patch is sufficiently increased, the number of the patches that can be included in one test chart is restricted. Accordingly, a test chart is desired in which the patches are aligned so as to lessen the effect of the leaked light as much as possible.

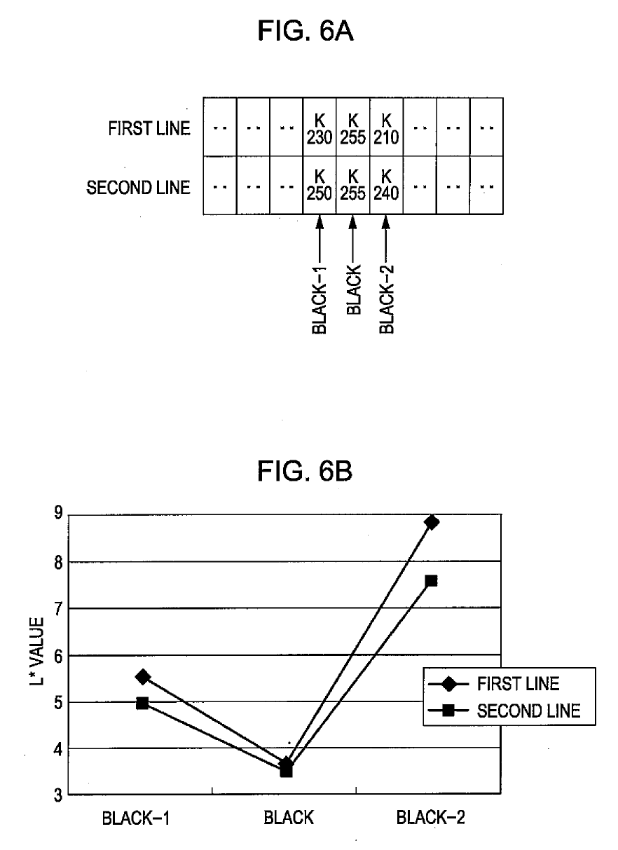

FIG. 6A is a diagram illustrating an arrangement of the black patches whose gradations are smoothly changed. In the first line, the black patches are aligned so that the gradation values become 230, 255, 210. In the second line, the black patches are aligned in the order so that the gradation values become 250, 255, 240. Herein, among the three black patches, the left one shall be “black-1” the center one shall be “black patch”, and the right one shall be “black-2”. Note that the size of the patches is 7 mm in the short side direction and 14 mm in the long side direction also in this case.

FIG. 6B is a diagram illustrating the L* value of the black patch when the gradations are smoothly changed. The L* value of the “black patch” of the first and the second lines in FIG. 6A is a value near 3.4, and is a value close to the L* value of the original black patch. In this manner, it is recognized that even when a patch having the completely same gradation value is not arranged at the both side, effect of the leaked light that is reflected by another patch to the calorimetric value of the patch of the colorimetric target can be lessened by arranging a patch having a relatively close gradation value.

In this case, as for the black patch, effect of the leaked light that is reflected by the adjacent patch to the calorimetric value of the patch of the calorimetric target can be lessened by arranging a patch having a close gradation value so as to be adjacent. The patches having colors whose distance in L*a*b* color space is close to each other shows colorimetric values that are close to each other. Accordingly, effect to the calorimetric value of the patch of the calorimetric target can be lessened even when the leaked light is reflected by the adjacent patch.

Accordingly, effect of the leaked light that is reflected by another patch to the calorimetric value of the patch of the calorimetric target can be lessened by arranging the patches whose L* values, a* values, b* values are respectively close so as to be adjacent to each other. Effect of the light that is reflected by the adjacent patch to the calorimetric value of the patch of the calorimetric target can be also lessened also by arranging the patches whose at least L* values are close so as to be adjacent to each other.

The gradation value corresponds to the lightness (L* value). Accordingly, even when colors of inks are different, if the gradation values thereof are close, the L* values showing the lightness are relatively close values. That is, by arranging the patches having close gradation values so as to be adjacent to each other, the patches whose at least L* values are close are arranged to be adjacent to each other even when the patches have different ink colors to each other. Accordingly, effect of the light that is reflected by another patch to the calorimetric value of the calorimetric target can be lessened.

Color Dispersion occurred on Surface of Paper

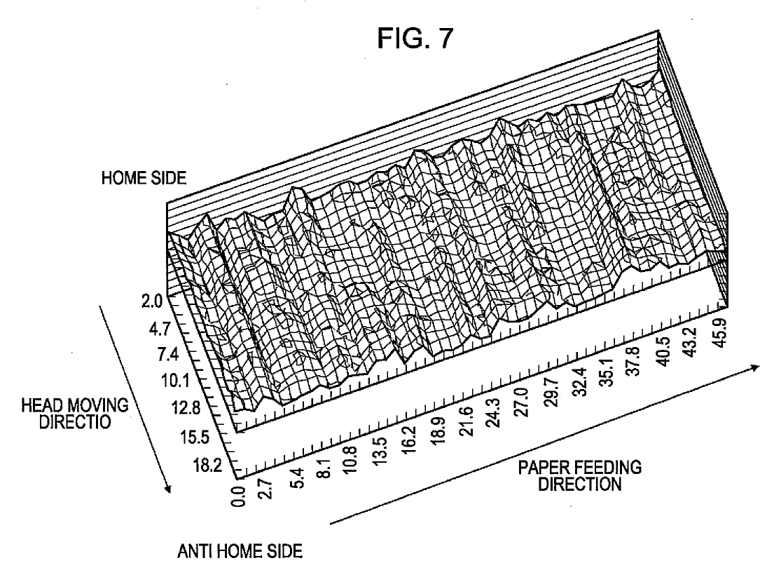

FIG. 7 is a diagram illustrating a level of color dispersion occurred on a surface of a paper when printing is performed on the paper.

In FIG. 7, the paper feeding direction is the paper feeding direction in the printer. Further, the head moving direction of the printer is shown in FIG. 7. The home side in the head moving direction is the home side at which the head of the printer stays, and the opposite side is shown as the anti home side. The vertical direction of the plane constituted by the axis of the paper feeding direction and the axis of the head moving direction shows a color dispersion level occurred on a surface of the paper.

Color dispersion levels changed by the position of the paper when a color having a certain gradation value of an ink is printed on the entire surface of one paper are shown in FIG. 7. The dispersion level is shown by a deviation with respect to the average value of the calorimetric values. When the average values of L*, a*, b* are respectively L*ₐᵥₑ, a*ₐᵥₑ, b*ₐᵥₑ, the deviation in the case is obtained by the following expression.

Deviation={(L*ₐᵥₑ−L*)²+(a*ₐᵥₑ−a*)²+(b*ₐᵥₑ−b*)²}^{1/2}

Note that herein, L*ave in L*, a*, b* color space shall be 88.0, a*ₐᵥₑ shall be −8.8, b*ₐᵥₑ shall be 58.9.

According to FIG. 7, a cyclic color dispersion is occurred in the paper feeding direction. It is considered that the cyclic color dispersion is occurred due to a cyclic difference of a transport amount caused by a roller of the printer 1 for feeding the paper whose shape is not a perfect circle.

There is a case that the color dispersion is locally occurred on the surface of the paper. In this case, when a plurality of patches having a certain ink color are arranged at a specific place in a concentrated manner, a calorimetric value that is affected by the color dispersion occurred on the surface may be obtained as for the ink color. Accordingly, it is desirable to arrange the patches of each ink color so as to be dispersed on the paper as far as possible. However, when the patches of a plurality of ink colors are arranged on the paper in a random manner so as to be dispersed, the patches having different ink colors are arranged so as to be adjacent to each other. Consequently, as described above, there is a possibility that the calorimetric value of the patch of the calorimetric target is affected by the reflected light that is leaked to the adjacent patch.

Accordingly, it is desirable to arrange the patches of different colors by an alignment by which effect of light reflected by the adjacent patch is lessened, while the patches of each ink color are dispersed as far as possible in order to avoid effect of color dispersion that is locally occurred.

As described above, the effect of the light reflected by the adjacent patch that is applied to the calorimetric value of the patch of the calorimetric target can be lessened by arranging the patches whose distance is close in L*a*b* color space so as to be adjacent to each other. Accordingly, even when ink color is different, by arranging the patches whose hue difference shown by a* value and b* value is small so as to be adjacent to each other, effect of the light reflected by the adjacent patch that is applied to the colorimetric value of the patch of calorimetric target can be lessened.

In the test chart of the embodiment shown below, the plurality of patches having different ink colors are arranged so that the gradation difference of the patches adjacent to each other becomes small in the short side direction of the patches. Further, the plurality of patches having different ink colors are arranged so that the hue difference of the patches adjacent to each other becomes small in the short side direction of the patches.

### Test Chart of the Present Embodiment

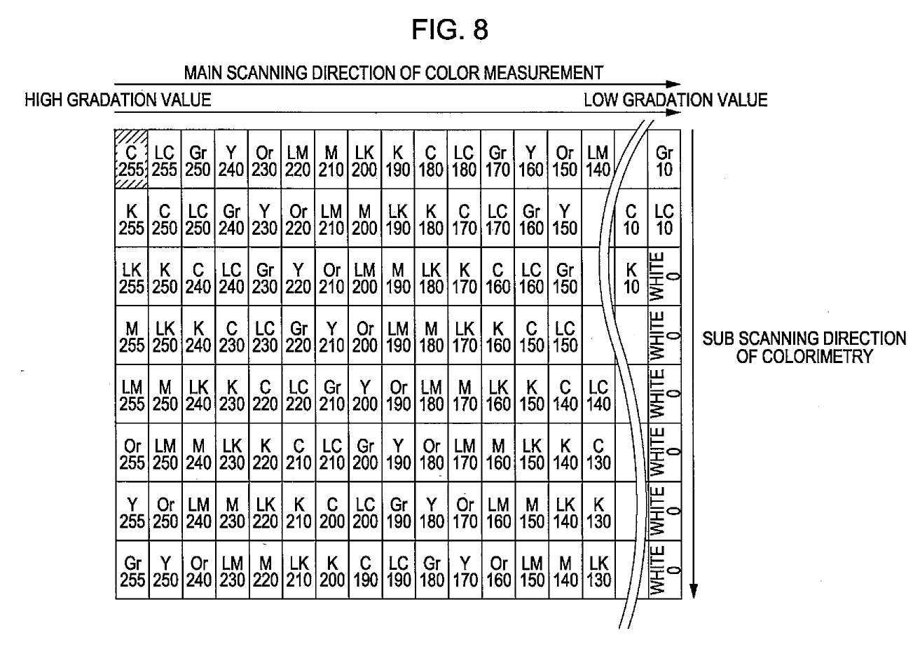

FIG. 8 is a diagram illustrating a test chart according to the embodiment. In the embodiment, the patch has a rectangular shape. Further, the size of the patch is 7 mm in the short side direction and 14 mm in the long side direction. Further, in the embodiment, the calorimetric area is included in one patch, whereas the light leaked area is provided over the adjacent patch in the short side direction as described above.

The ink colors used in the embodiment are cyan C, light cyan LC, green Gr, yellow Y, orange Or, light magenta LM, magenta M, light back LK, and black K. Then the patches of the ink colors are aligned so as to be adjacent to each other in the short side direction and the long side direction. Further, gradation values by which printing is performed are shown below the ink colors in FIG. 8.

In FIG. 8, it is shown that the short side direction of the patches is the main scanning direction of the head 43 of the calorimeter 40. The long side direction of the patches is the sub scanning direction of the calorimeter 40. That is, the calorimeter 40 performs colorimetry on each patch while moving the head 43 in the short side direction of the patches. Then, when the colorimetry of the patches of the first row is completed, the test chart is transported in the sub scanning direction by one row of the patch, and the calorimetric of the next row is to be performed.

Incidentally, oblique lines are drawn for one patch in FIG. 8. The oblique lines show a reference of the position of the patch for the description to be described below. The patch in which the oblique lines are drawn shall be the patch of first row and first column. The number of row shall be increased as is advanced in the long side direction, and the number of column shall be increased as is advanced in the short side direction. For example, the patch of light cyan adjacent to the patch of the oblique lines in the short side direction is the patch of first row and second column, and the patch of the black K adjacent to the patch of the oblique lines in the long side direction is the patch of the second row and first column.

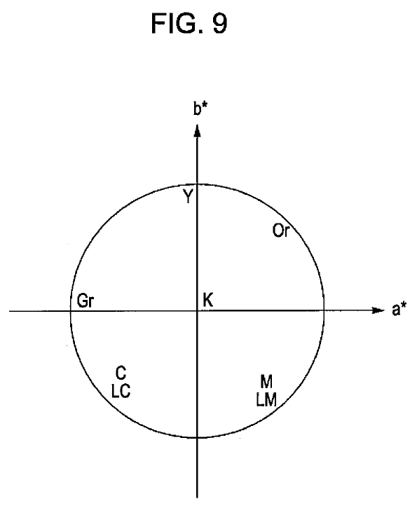

FIG. 9 is a diagram illustrating a hue angle in L*a*b* color space. In FIG. 9, a* axis and b* axis of L*a*b* color space are shown. L* exists in the vertical direction of the paper surface from the center of a* axis and b* axis although omitted in FIG. 9.

Rotation about the L* axis is shown as the hue angle. As a hue angle difference of ink colors becomes smaller, the hue difference becomes small. In FIG. 9, when rotated about the L* axis in the clockwise direction, magenta M and light magenta LM exist at the next of orange Or. When rotated furthermore in the clockwise direction, cyan C exists. That is, the hue of orange Or is closer to that of magenta M having a smaller hue angle difference than that of cyan C having a larger hue angle difference.

Accordingly, when the ink colors of the embodiment are aligned in the order of closeness of hue, the ink colors are aligned in the order of orange Or, magenta M, light magenta LM, cyan C, light cyan LC, green Gr, yellow Y. Accordingly, the patches whose distance in L*a*b* color space is close are to be closely arranged to each other by aligning the colors in the order also in the test chart.

Incidentally, L* value of the color of black K having a high density becomes a value close to 0. Further, in the inks used in the embodiment, L* value is reduced if the density of magenta M and cyan C is increased. On the other hand, in the ink used in the embodiment, there is a tendency that the lightness of the yellow Y and orange Or is high even when the density of the yellow Y and orange Or is high. Under the circumstances, the hue difference with respect to the patch of black K can be reduced when the patches of magenta M and cyan C whose L* values are lowered as the density becomes higher similarly to black K are arranged to be adjacent to the patch of black K than when the patches of yellow Y and orange Or are arranged to be adjacent to the patch of black K. Accordingly, in the embodiment, the patches of black K and light black LK are to be arranged between the patches of magenta M and cyan C.

In light of the aforementioned conditions, the patches of the embodiment are repeatedly aligned in the order of cyan C, light cyan LC, green Gr, yellow Y, orange Or, light magenta LM, magenta M, light black LK, and black K in the short side direction. Herewith, the plurality of patches having different ink colors can be aligned so that the hue difference of the patches adjacent to each other is reduced in the short side direction of the patches.

Note that the order of the ink colors of the patches aligned in the long side direction (row number increasing direction) is black K, light black LK, magenta M, light magenta LM, orange Or, yellow Y, green Gr, light cyan LC, and cyan C. In the alignment, black K and light black LK are added to the alignment of the ink colors when the aforementioned hue angle is rotated in the anti clockwise direction.

Further, the number of rows of the test chart in the embodiment is set smaller than the number of ink colors to be used by one. For example, nine colors of ink colors are used here, whereas the number of rows of the test chart is set to eight rows. Then, the patches having different ink colors and having the same gradation value are aligned in the order of the aforementioned ink colors in the long side direction of the patches. The number of the rows is smaller than the number of the ink colors by one row, so that there exists a patch that can not be aligned in the same column. In this case, the patch that can not be aligned in the same column is arranged from the first row of the next column. In this manner, when the patches corresponding to the nine colors having the same gradation value are aligned, next, the patches having a lower gradation value are aligned at the following positions in the similar order. Also in this case, the patches having different ink colors and having the same gradation value are aligned in the order of the aforementioned ink colors in the long side direction of the patches. In this manner, the patches are arranged till the gradation value becomes zero (white color).

For example, as shown in FIG. 8, the patches whose gradation value is 255 are aligned in the order of cyan C, black K, light black LK, magenta M, light magenta LM, orange, Or, yellow Y, green Gr, from 1st row and 1st column to 8th row and 1st column. Then, the patch of light cyan LC whose gradation value is 255 is aligned at 1st row and 2nd column. Next, the patches of nine colors whose gradation value is 250 are aligned in the similar order of the ink colors. The arrangement of the patches is performed till the gradation value becomes zero (white color).

Herewith, the patches can be arranged so that the gradation value of the patch whose column number is small becomes not less than the gradation value of the patch whose column number is large as for the short side direction of the patches. In other words, as the column number becomes larger, the patch having a smaller gradation value is to be aligned. In addition, the pluralities of patches having different colors are aligned so that the gradation difference of the patches adjacent to each other becomes small in the short side direction of the patches.

Further, the number of rows of the test chart is smaller than the number of ink colors by one. Accordingly, if the patches are arranged as described above, the patches are aligned so that the ink colors are aligned in the clockwise order of the hue angle in the short direction of the patches. In addition, the pluralities of patches having different ink colors are aligned so that the hue difference of the patches adjacent to each other becomes small in the short side direction of the patches.

By arranging the patches in this manner, the plurality of patches having different ink colors can be aligned so that the distance between ink colors of the adjacent patches in L*a*b* color space becomes small in the short side direction of the patches as the whole test chart while dispersing the patches of each ink color.

In this manner, since the plurality of patches having different ink colors are arranged so that a difference of hue between the adjacent patches becomes small in the short side direction of the patches, effect of the light reflected by the adjacent patch that is applied to the calorimetric value of the patch of the calorimetric target can be lessened. Further, since the patches having close gradation values are arranged so as to be adjacent to each other, the patches at least whose L* values are relatively close are arranged so as to be adjacent to each other even when the patches have different ink colors to each other. Consequently, effect of the light reflected by the adjacent patch that is applied to the calorimetric value of the patch of the calorimetric target can be lessened. Herewith, effect of another patch can be lessened when performing calorimetry.

### Other Embodiments

The aforementioned embodiment is an embodiment that facilitates understanding of the invention and is not an embodiment to limit the invention. Modifications and changes can be made to the invention without departing from the spirit of the invention, and it goes without saying that such modifications and changes are included in the invention.

The entire disclosure of Japanese Patent Application No: 2008-053813, filed Mar. 4, 2008 is expressly incorporated by reference herein.

What is claimed is:

1. A test chart used for a color calibration for correcting gradation, wherein
the test chart includes a plurality of rectangular patches respectively corresponding to each gradation for each color, and the plurality of patches having different colors are aligned in the order so that the colors whose hues are close become adjacent to each other in a short side direction of the patches.

2. The test chart according to claim 1, wherein
the plurality of patches having different colors are aligned in the order of the patch having higher gradation in the short side direction of the patches in the test chart.

3. The test chart according to claim 1, wherein
the plurality of patches having different colors are aligned so that a gradation difference of the patches adjacent to each other becomes small in the short side direction of the patches.

4. The test chart according to claim 1, wherein
the plurality of patches having different colors are aligned so that a distance of colors of the patches adjacent to each other in a color space becomes close.

5. The test chart according to claim 4, wherein the color space is CIE L*a*b* color space.

6. The test chart according to claim 1, wherein
the plurality of patches having different colors are also aligned so that a hue difference of the patches adjacent to each other becomes small in the long side direction of the patches.

7. A calibration method comprising:
performing colorimetry on a test chart that includes a plurality of rectangular patches respectively corresponding to each gradation for each color, the plurality of patches having different colors being aligned in the order so that the colors whose hues are close become adjacent to each other in a short side direction of the patches; and
performing a color calibration based on a calorimetric result of the test chart.
